(19) United States
(12) Patent Application Publication
(10) Pub. No.: US 2013/0206203 A1
(43) Pub. Date: Aug. 15, 2013

(54) PHOTOVOLTAIC MODULE WITH INTEGRATED SOLAR CELL DIODES

(71) Applicants: Timothy Charles Lommasson, Heggedal (NO); Eckehard Hofmûller, Oslo (NO)

(72) Inventors: Timothy Charles Lommasson, Heggedal (NO); Eckehard Hofmûller, Oslo (NO)

(73) Assignee: INNOTECH SOLAR ASA, Narvik (NO)

(21) Appl. No.: 13/818,872

(22) PCT Filed: Aug. 19, 2011
(86) PCT No.: PCT/NO2011/000227

§ 371 Date: Apr. 18, 2013

(30) Foreign Application Priority Data
Aug. 26, 2010 (NO) 20101194

(51) Int. Cl. H01L 31/05

(52) U.S. Cl. CPC H01L 31/0504
USPC 136/244; 438/59

(57) ABSTRACT

A solar module having a plurality of series connected pn junction production solar cells, where at least one bypass diode (2) is provided with a surface area adapted to dissipate heat generated from one or more of the series connected production cells. A substantial part of the surface area is disposed substantially flush with the front and/or rear face of a production cell. The bypass diode (2) is electrically connected in parallel and with opposite polarity to at least one production cell (1) by electrical conductors (3).

### TECHNICAL FIELD

The present invention relates to an apparatus and method for protecting solar cells from the effects of shading, in particular reverse bias, reverse current and hotspots caused by shading. In particular it is provided a solar module comprising a plurality of series connected pn junction production solar cells, where at least one bypass diode is provided, it is also provided a method for producing the same.

### BACKGROUND ART

Within a solar module typically a plurality of solar cells are connected in series to provide technically useful voltages and currents. In case of partial shadowing of the solar module, the shadowed solar cells will generate less or even no current and will not conduct the current in the normal forward bias mode. (The current in a series connected string of cells must be the same in all cells.) The voltage of the illuminated cells will build up a reverse bias voltage on the shadowed cells until a steady state current is reached. The reverse bias voltage on a shadowed cell may reach values higher than the break-down voltage of the shadowed cell. This can permanently damage the cell and the module. Solar cells can be protected by installing bypass diodes in parallel to the solar cells.

Examples of integrated bypass diodes protecting a single solar cell can be found in, for example, U.S. Pat. No. 6,184,458, U.S. Pat. No. 5,616,185, U.S. Pat. No. 5,223,044 and U.S. Pat. No. 6,784,358. The integrated diodes in these references are thin and/or narrow. A typical thin film diode cannot withstand typical currents in a modern high efficiency 15 cm (6 inch) silicone crystalline cell, such as about 8.5 A. Furthermore, a thin or narrow diode also generates heat when employed in a modern cell or module with higher currents. As the surface area of a thin and narrow structure tends to be too small to radiate away the heat to the surrounding environment, such diodes often require good thermal coupling to a heat sink with a sufficiently large surface area to dissipate the excess heat by radiation. Accumulated heat could cause overheating and permanent damage on the solar cell and the module, and adding good thermal conductors which do not conduct electricity to numerous small diodes quickly adds to the complexity and cost of a solar module producing voltages and currents for present applications. Further, integrating the diodes in a solar cell such as in the above references tends to be complicated, and increases the risk of breakage and yield losses.

U.S. Pat. No. 5,330,583 entitled ‘Solar Battery Module’ to Asai et al. describes a solar battery module that includes interconnectors for series-connecting a plurality of solar battery cells, and one or more bypass diodes which allow output currents of the cells to be bypassed with respect to one or more cells. Each diode is a chip-shaped thin diode and is attached on an electrode of a cell or between interconnectors. More particularly, the chip-shaped bypass diodes are either connected to a front surface of the solar battery or are positioned to the side of a solar battery or are connected to rear surface of a solar battery to protect a string of solar batteries.

Today, common practice is to install one bypass diode in parallel over 20 cells, as this is found to be a reasonable compromise between a desire to limit the maximum reverse bias and reverse current, both of which increase with the number of solar cells, and a desire to limit the number of bypass diodes, which adds to the complexity and cost of diode integration and wiring. Typically, the diodes are installed in a junction box on the back or rear side of the module. The junction box is thermally connected to a heat sink, and may be overheated if the heat sink is too small to dissipate the heat. If cells with low reverse voltage resistance are used, diodes need to be installed parallel to a lower number of cells, so that the total number of diodes per module will be increased. However, increasing the number of bypass diodes within external junction boxes is likely to increase the number of boxes, the amount of required wiring and/or add to the complexity of the boxes. This quickly increases the cost and complexity of the module.

WO2009/012567 entitled ‘Shading protection for solar cells and solar cell modules’ to Day4Solar describes a solar module wherein each solar cell gets a chip diode mounted on its rear side. The chip diode is used as bypass diode. However, chip diodes are small and do not dissipate heat effectively as discussed above. Effectively this solution simply moves a potential hot spot from a cell to its bypass diode.

GB1243109 entitled ‘Use of un-illuminated solar cells as shunt diodes for a solar cell area’ assigned to NASA, discloses a solar cell array comprising at least two batteries, each having a plurality of series connected pn junction solar cells, arranged so that one of the batteries is illuminated whilst the other is shaded. Each solar cell of one battery is connected in parallel and opposite polarity with a cell in the other battery, so that if a solar cell in the illuminated battery becomes disabled, the solar cell connected in parallel with it in the shaded battery provides a shunt path around it. The polarity of the voltages developed by the illuminated solar cells is such as to reverse bias the equivalent diodes of the unilluminated solar cells and prevent shorting under normal operation, but if one of the solar cells in the illuminated battery is shaded and ceases to generate a voltage the equivalent diode of the shaded solar cell connected in parallel with it is forward biased and conducts, thus ensuring a continuous current path. The batteries may be mounted on a space craft.

While the idea of using a large number of diodes to reduce the maximum possible reverse current seems viable, providing a separate solar module would be impractical, expensive and complicated in terrestrial applications, where a solar module typically is mounted on a surface such as a wall or rooftop, and there hence would be only one active face of the module and no need for a second module or battery of solar cells.

Hence, it is an objective of the present invention to incorporate a high number of diodes into a solar module, thereby reducing the maximum possible reverse current voltage. Furthermore, it is an objective to improve the heat dissipation from the bypass diodes, while keeping the complexity and cost low.

### DISCLOSURE OF INVENTION

According to the present invention, this is achieved by providing a solar module comprising a plurality of series connected pn junction production solar cells, wherein at least one bypass diode is provided with a surface area adapted to dissipate heat generated by a voltage and current from one or more of the series connected pn junction production solar cells, where a substantial part of the surface area of the at least one bypass diode is disposed substantially flush with the front and/or rear face of a production solar cell, and the bypass diode is electrically connected in parallel and with opposite polarity to at least one production solar cell by electrical conductors and where the at least one bypass diode (2) is a solar cell disposed with its rear side facing in the same direction as the front face of the production solar cell.

According to one aspect of the invention the bypass diode is provided as a part of a solar cell.

According to another aspect of the invention the production cells are arranged into strings, each string comprising at least one production cell, and each string being electrically connected to one bypass diode.

According to yet another aspect of the invention the bypass diode is provided with an optically reflective surface.

According to yet another aspect of the invention the electrical connectors are disposed between the cells.

According to yet another aspect of the invention the electrical connectors are optically reflective.

As a large surface area is disposed substantially flush with the front and/or rear surface of the module, excess heat can be dissipated by radiation directly from the diode surface, rather than being conducted to an external heat sink or radiator. This may reduce or eliminate the requirement for an external heat sink or radiator and a thermal conductor between the diodes and the external heat sink. The area of the diode should be large enough to ensure that heat is dissipated at moderate temperatures, i.e. temperatures well below those that will harm or damage the module or its component parts.

In some embodiments, the large area bypass diode may be all or part of a solar cell mounted “upside down” in the module. As most of the required wiring is already present in a solar cell, connecting a solar cell as a bypass diode is a convenient and economic choice, in particular because a solar cell acting as a bypass diode can be built into the module in much the same manner as the production cells.

The invention also provides a method for producing such a solar module.

In particular it is provided a method for producing a solar module having a plurality of series connected pn junction production solar cells at least comprising the steps of:
providing a bypass diode with a surface area adapted to dissipate heat generated by a maximum voltage and current generated by one or more of the series connected production cells,
disposing the bypass diode with a substantial part of the surface area substantially flush with the front and/or rear face of a production cell, and
connecting the bypass diode electrically in parallel and with opposite polarity to at least one production cell using electrical conductors.

According to one aspect of the invention the method further comprises the step of providing a part of a solar cell and using it for the bypass diode.

According to yet another aspect of the invention the method further comprises the step of disposing the part of the solar cell with its rear side facing in the same direction as the front side of the production cell.

According to yet another aspect of the invention the method further comprises the step of arranging the production cells into strings, each string comprising at least one production cell, and each string being electrically connected to one bypass diode.

According to yet another aspect of the invention the method further comprises the step of providing the bypass diode and/or electrical conductors with an optically reflective surface.

According to yet another aspect of the invention the method further comprising the step of slicing a standard solar cell into stripes for use as the at least one bypass cell.

According to yet another aspect of the invention the method further comprises the step of adapting the size of a stripe to a need for heat dissipation.

The advantages of the present solution include:
Heat generated during diode operation is dissipated at moderate temperatures.
No need for an external heat sink or thermal connections to the junction box
Simple integration of bypass diodes into the electrical circuits (stringing and tabbing) of a solar module
Simple integration of bypass diodes into the laminate of a solar module
Protection level down to one bypass diode per solar cell is possible
Simple junction box with no diodes and extra wiring

Materials used are all well proven in laminates for long life times

### BRIEF DESCRIPTION OF DRAWINGS

The invention will be more fully disclosed in the following detailed description with reference to the accompanying drawings, where:

FIG. 1 shows a solar cell protected by a bypass diode.

FIG. 2 illustrates a full size module where each cell is connected to an individual bypass diode.

FIG. 3 shows a module arranged as a series of strings of cells, each string of cells using one stripe of a solar cell as a bypass diode.

FIG. 4 shows another embodiment wherein each production cell is protected by a bypass diode.

FIG. 5 shows a detail from the module of FIG. 4.

### MODE(S) FOR CARRYING OUT THE INVENTION

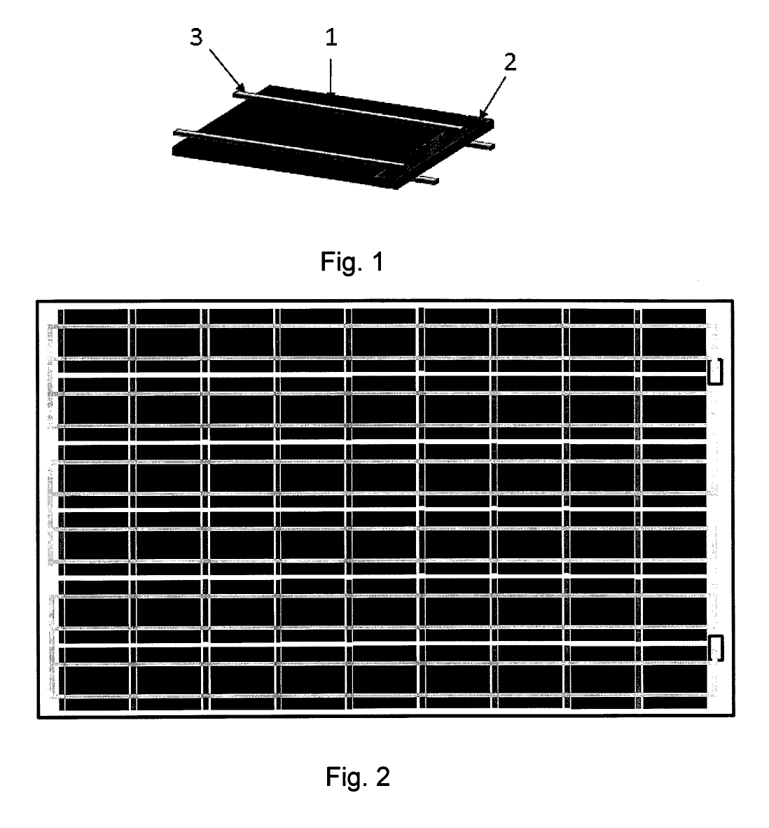

FIG. 1 shows a single solar cell protected by a bypass diode 2. The diode is electrically connected in parallel to one or more production cells 1 by electrical connectors 3, and provides a path for the reverse currents generated when one or more of the production cells 1 are shaded as discussed in the introduction.

The wording connector(s) 3 or ribbon(s) are used interchangeably throughout the description to describe conductors interconnecting for example production cells and bypass diodes.

A solar module comprises a plurality of single solar cells. The maximum heating in a module occurs when one cell in a string 5 is shaded or partially shaded so that it 5 does not produce enough light generated current in forward bias to match the current generated by all the other unshaded cells in the same string 5 and hence goes into reverse bias as the current is forced through the shaded cell by the potential created by all the unshaded cells in the same string 5. Or the maximum heating occurs when the current goes through a bypass diode 2 when driven by the potential of other series connected strings 5 in the module. The excess heat is, according to the present invention, dissipated by radiation through a surface area of the diode 2. It is noted that radiation from the sun and other factors may contribute to excess heat in a diode disposed within a solar module, and that the absorption and radiation will, among other factors, depend on the heat capacity, thermal conductivity, colour and reflectivity of the diode, etc. These and other relevant factors are known to one skilled in the art, and hence they are not discussed in detail here. For the purposes of the present disclosure, it is noted that the above mentioned maximum contribution to excess heat obtained when all solar cells are shaded can be used to calculate the surface area of the bypass diode, as the ability to radiate excess heat by the bypass diode 2 is dependent of the surface area of the bypass diode 2. The actual excess heat generated by the production cells 1 will be less than or equal to this maximum value. Alternatively, the surface area of the bypass diode in a particular application can be determined by performing a limited set of tests known by one skilled in the art.

Further, the bypass diode 2 may be a substantially flat stripe of material comprising two surfaces, e.g. a front surface and a rear surface, which are substantially larger than the lateral surfaces. This means that almost all excess heat is dissipated through the front and/or rear surfaces, and only a negligible fraction is dissipated through the lateral surfaces. A substantial part of the surface area of the bypass diode 2 is disposed substantially flush with the front and/or rear face of a production cell 1 and the bypass diode 2 is further arranged adjacent to said production cell 1 where one of its 2 lateral sides are substantially parallel with one of the lateral sides of the production cells 1.

Crystalline silicon solar cells can be regarded as large area pn-junctions. A space charge region is typically formed by doping the front side of the cell with phosphorous while the bulk of the cell is slightly boron doped. Exposed to light, free charge carriers are generated within the cell resulting in a light induced current. On the other hand, when the cell is shaded it has a characteristic similar to a rectifier diode. The large area of those cells makes them suitable as high current diodes. Solar cell pieces of few cm² are thus enough to be used as bypass diodes with good heat dissipation.

Thus, in some embodiments, the bypass diode 2 can constitute the full or a part of an industrial solar cell disposed upside down in a solar module, i.e. having its rear face facing in the same direction as the front faces of the production cells 1. It should be clearly understood that heat can be dissipated by radiation directly from any bypass diode having a sufficiently large surface area, and that a solar cell just may be a convenient and economic way of providing a large area bypass diode. In particular, it is noted that a solar cell includes wiring and has a thickness and other characteristics that makes it relatively easy to incorporate an entire cell or a stripe of it into a solar module comprising solar cells with similar wiring, dimensions, well proven durability, resistivity to sunlight, compatibility with the coatings used in a solar module and other characteristics.

In the drawings, interconnection ribbons 3 are used to electrically contact the solar cells. The electrical conductors 3 may be extended over the bypass diode and put the diode electrically in parallel to the cell. As indicated above, this connection may be easily accomplished if the bypass diode 2 is a solar cell having similar wiring as production cells 1. Again, it is noted that the bypass diode 2 can be any diode with a sufficiently large surface area. The bypass node can constitute a part of a solar cell or the whole solar cell.

Each solar cell of a solar module may be provided with such a bypass diode 2. In case of partial shadowing of the module all non shadowed cells will be fully operating while the diodes are bypassing the current around the shaded cells. The bypass diode may be provided with an optically reflective surface, e.g. obtained by coating the surface with a reflective material, covering it with a reflective film, etc. The purpose is partially to redirect incident sunlight to one or more adjacent production cells, and partially to reduce the heat imposed on the bypass diode by incoming radiation, e.g. by sunlight.

FIG. 2 illustrates a full size module with 54 solar cells, where each cell is connected to an individual bypass diode.

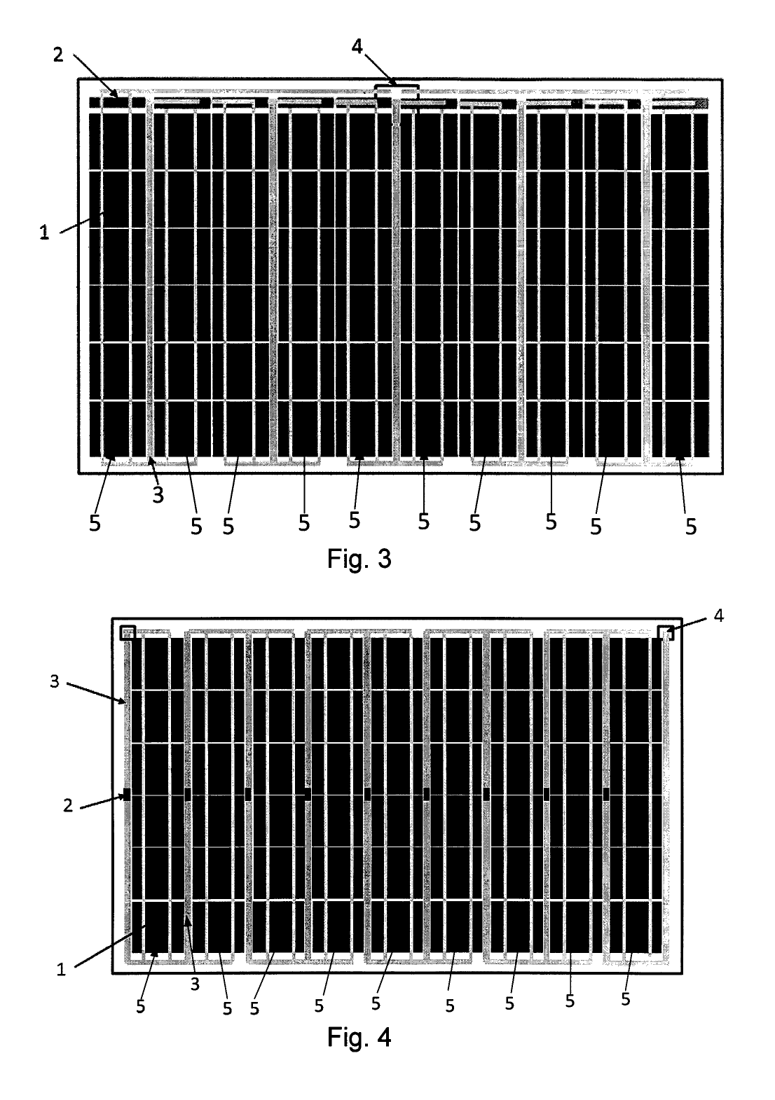

FIG. 3 shows another possible embodiment of the invention. In this case the module comprises ten strings 5, each string 5 having six production cells 1. At the end of each string is one stripe of a solar cell placed facing to the back side of the module. Each stripe of solar cell acts as a bypass diode 2 and is connected in parallel and with opposite polarity with regard to the six production cells 1 in the string 5 it protects. Having one bypass diode 2 parallel to six cells, the maximum reverse voltage which may occur over a single cell is limited to 3 V. This particular module design requires an additional cross connector 3 between the strings. This cross connector 3 may be placed behind the cells or between the cells. If the cross connection is provided between the cells, it may be provided with a reflective surface to redirect incoming light to the adjacent cells, and/or to reduce the heat absorbed from the sunlight. Silver is commonly used in the electrical connectors, known as fingers and bus bars, on the front face of solar cells. It is well known that silver is a good optical reflector as well as being a good electrical connector. Silver may hence be an example of a choice of material that needs no special coating to be reflective. In other cases, a reflective coating or film provided over the wiring (and/or bypass diodes) may be beneficial.

In FIG. 4 another embodiment of the invention is illustrated. Six solar cells 1 are connected in a string 5 while each string 5 gets its own bypass diode 2 connected to both ends of the string 5 by wide cross connectors 3 placed parallel to the string 5. The cross connectors 3 may be provided with a reflective surface to redirect the incident light to the adjacent solar cells and/or reduce heat absorption as discussed above.

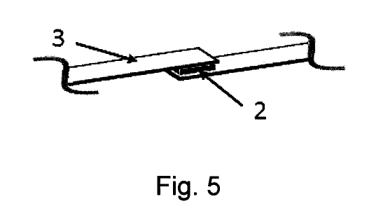

FIG. 5 shows a detail of the module shown in FIG. 4 to illustrate the incorporation of the bypass diode 2. This diode may be a piece cut out from an industrial solar cell or a large area chip diode, such that heat is dissipated from its relatively large area in an efficient manner. The bypass diode 2 is electrically connected on the top side as well as on the bottom side to a section cross connector 3 of suitable length. The power dissipated in the diode will lead to limited temperature increase not only because the bypass diode 2 is of a suitable large area but also because the wide cross connectors 3 will help to conduct and radiate the generated heat.

1. A solar module comprising a plurality of series connected pn junction production solar cells, where at least one bypass diode is provided with a surface area adapted to dissipate heat generated by a voltage and current from one or more of the series connected pn junction production solar cells, where a substantial part of the surface area of the at least one bypass diode is disposed substantially flush with the front and/or rear face of a production solar cell, and the bypass diode is electrically connected in parallel and with opposite polarity to at least one production solar cell by electrical conductors and where the at least one bypass diode is a solar cell disposed with its rear side facing in the same direction as the front face of the production solar cell.

2. The solar module of claim 1, wherein the bypass diode is provided as a part of a solar cell.

3. The solar module of claim 1, wherein the production cells are arranged into strings, each string comprising at least one production cell, and each string being electrically connected to one bypass diode.

4. The solar module of claim 1, wherein the bypass diode is provided with an optically reflective surface.

5. The solar module of claim 1, wherein the electrical connectors are disposed between the cells.

6. The solar module of claim 1, wherein the electrical connectors are optically reflective.

7. A method for producing a solar module having a plurality of series connected pn junction production solar cells, at least comprising the steps of:
providing a bypass diode with a surface area adapted to dissipate heat generated by a maximum voltage and current generated by one or more of the series connected production cells,
disposing the bypass diode with a substantial part of the surface area substantially flush with the front and/or rear face of a production cell, and
connecting the bypass diode electrically in parallel and with opposite polarity to at least one production cell using electrical conductors.

8. The method of claim 7, further comprising the step of providing a part of a solar cell and using it for the bypass diode.

9. The method of claim 8, further comprising the step of disposing the part of the solar cell with its rear side facing in the same direction as the front side of the production cell.

10. The method of claim 7, further comprising the step of arranging the production cells into strings, each string comprising at least one production cell, and each string being electrically connected to one bypass diode.

11. The method of claim 7, further comprising the step of providing the bypass diode and/or electrical conductors with an optically reflective surface.

12. The method of claim 7, further comprising the step of slicing a standard solar cell into stripes for use as the at least one bypass cell.

13. The method of claim 12, further comprising the step of adapting the size of a stripe to a need for heat dissipation.

14. The solar module of claim 2, wherein the production cells are arranged into strings, each string comprising at least one production cell, and each string being electrically connected to one bypass diode.

15. The solar module of claim 2, wherein the bypass diode is provided with an optically reflective surface.

16. The solar module of claim 3, wherein the bypass diode is provided with an optically reflective surface.

17. The solar module of claim 14, wherein the bypass diode is provided with an optically reflective surface.

18. The solar module of claim 2, wherein the electrical connectors are disposed between the cells.

19. The solar module of claim 3, wherein the electrical connectors are disposed between the cells.

20. The solar module of claim 14, wherein the electrical connectors are disposed between the cells.
